(19) United States
(12) Patent Application Publication
(10) Pub. No.: US 2026/0039297 A1
(43) Pub. Date: Feb. 5, 2026

(54) METHODS AND SYSTEMS FOR CONTROLLING A SYSTEM OF SUPERCONDUCTING QUBITS USING SINGLE FLUX QUANTUM (SFQ) PULSES

(71) Applicant: 1QB Information Technologies Inc., North Vancouver (CA)

(72) Inventors: Florian HOPFMUELLER, Montreal (CA); Bohdan KULCHYTSKYY, Waterloo (CA); Ross Aaron SHILLITO, Quebec City (CA); Pooya RONAGH, Guelph (CA)

(21) Appl. No.: 19/354,601

(22) Filed: Oct. 9, 2025

Related U.S. Application Data
(63) Continuation of application No. PCT/IB2024/053518, filed on Apr. 10, 2024.
(60) Provisional application No. 63/495,506, filed on Apr. 11, 2023.

(51) Int. Cl. H03K 17/92; G06N 10/40

(52) U.S. Cl. CPC H03K 17/92; G06N 10/40

(57) ABSTRACT

Methods and systems for controlling a system of superconducting qubits using single flux quantum (SFQ) pulse schedule is provided. The single flux quantum (SFQ) pulse schedule may comprise on-ramp, off-ramp, and resonant parts, wherein the frequency of a single flux quantum (SFQ) pulse clock is at about a multiple of a qubit frequency. The method may include: providing a system of one or more qubits; delivering a single flux quantum (SFQ) pulse to each of the one or more qubits, the single flux quantum (SFQ) pulse being capable of influencing a quantum state of a qubit; obtaining at least one single flux quantum (SFQ) pulse schedule for the one or more qubits, each schedule comprising on-ramp, resonant, and off-ramp parts; and implementing the at least one single flux quantum (SFQ) pulse schedule for the one or more qubits.

### CROSS-REFERENCE

This application is a continuation of International Application No. PCT/IB2024/053518 filed Apr. 10, 2024, which claims the benefit of U.S. Provisional Application No. 63/495,506, filed Apr. 11, 2023, each of which is incorporated by reference herein in its entirety for all purposes.

### BACKGROUND

Recent years have seen an effort, within both academia and industry, towards constructing a quantum computer capable of solving scientifically and industrially relevant computational problems. One approach to building such a device is based on superconducting qubits, which may be controlled with room-temperature microwave electronics. In the superconducting approach, in order to solve computational problems of a relevant size, it may be advantageous to scale up superconducting quantum processors to contain more qubits while continuing to improve the quality of the qubits and quantum gates.

One of the challenges of scaling a system with room-temperature microwave electronics is the increasing complexity of bringing the analog control signals to the individual qubits, which may involve the use of many cables connecting the room-temperature electronics to cryogenic qubits. This may pose challenges in routing, avoiding heating, and the introduction of errors from the cables and control electronics. In addition, such complexity may involve increases in costs since the hardware may be expensive.

### SUMMARY

Recognized herein is the need for improved methods and systems that can overcome at least one of the drawbacks identified herein. The present disclosure provides methods and systems for controlling a system of superconducting qubits using a single flux quantum (SFQ) pulse schedule comprising on-ramp, off-ramp, and resonant parts.

Disclosed herein are methods for developing pulse sequences which implement single-qubit gates, and systems which deliver them to the qubits.

The current disclosure presents a system for single-qubit control using simple pulse sequences, formed by prepending and appending short, optimized pulse sequences to a resonant pulse sequence. Simulations show that this approach allows single-qubit control with excellent fidelity and low leakage, while being compatible with the constraints of designing SFQ electronics co-located with the qubits. The approach is also compatible with obtaining a large set of well-performing single-qubit gates, by varying the length of the resonant part of the pulse schedule, keeping the prepended and appended pulse sequences (e.g., the on-ramp and off-ramp pulse sequences described herein) fixed. The technology presented herein is therefore an important advancement over existing schemes and may be a key enabler of scaling superconducting quantum computers using SFQ control technology.

In an aspect, the present disclosure provides a method for controlling a system of superconducting qubits using at least one single flux quantum (SFQ) pulse schedule, wherein a frequency of an SFQ pulse clock is at about a multiple of a qubit frequency. The method may comprise: (a) delivering an SFQ pulse to one or more qubits of said system of superconducting qubits, said SFQ pulse being capable of influencing a quantum state of a qubit; (b) obtaining said at least one SFQ pulse schedule for said one or more qubits, wherein said at least one SFQ pulse schedule comprises an on-ramp part, a resonant part, and an off-ramp part; and (c) implementing said at least one SFQ pulse schedule for said one or more qubits.

In some embodiments, said superconducting qubits comprise transmon qubits or fluxonium qubits. In some embodiments, (b) comprises: (i) obtaining an indication of one or more target single-qubit gates each having a target angle; and (ii) using an optimization protocol to select said at least one SFQ pulse schedule, wherein said optimization protocol uses said one or more target single-qubit gates and said frequency.

In some embodiments, (b) further comprises: (iii) obtaining properties of said system of said one or more qubits allowing for simulation of a quantum state of said system of said one or more qubits using a digital computer; (iv) obtaining an indication of an SFQ pulse effect on said system of said one or more qubits; (v) obtaining said frequency of said SFQ pulse clock; and (vi) scheduling arrivals of said SFQ pulses; wherein said optimization protocol comprises simulating a quantum state of said one or more qubits using said digital computer.

In some embodiments, (ii) comprises: (1) selecting a group of SFQ pulse schedules, wherein each SFQ pulse schedule in said group comprises on-ramp, resonant, and off-ramp parts; (2) providing said each SFQ pulse schedule in said group to said one or more qubits; (3) performing a group of experiments, wherein each experiment comprises: initializing a quantum state of said one or more qubits using said each SFQ pulse schedule one or more times, and performing a quantum state measurement to obtain results; and (4) comparing said results obtained in (3) to expected results of said one or more target single-qubit gates to select said at least one SFQ pulse schedule.

In some embodiments, said optimization protocol comprises at least one member of the group consisting of: exhaustive search, gradient based optimization, gradient-free optimization, genetic algorithms, reinforcement learning, machine learning, heuristics for limiting the search space, tree search, and manual search.

In some embodiments, said properties of said system of said one or more qubits comprise: properties of individual qubits and properties of interactions between said one or more qubits. In some embodiments, said indication of said SFQ pulse effect on said system of said one or more qubits comprises a kick angle, wherein said kick angle comprises a rotation angle of a quantum state of a qubit in a Hilbert space resulting from an SFQ pulse. In some embodiments, said properties of said system of said one or more qubits comprise a frequency and an anharmonicity of each of said one or more qubits.

In some embodiments, said on-ramp part comprises a sequence of arrivals of said SFQ pulses, wherein arrival times within said sequence of arrival times are determined at least in part by said SFQ pulse clock, and wherein a length of said sequence is determined at least in part by a number of periods of said SFQ pulse clock frequency. In some embodiments, said resonant part comprises a resonant pulse train comprising a pattern of arrivals of SFQ pulses, wherein said pattern of arrivals repeats at about a qubit frequency. In some embodiments, said off-ramp part comprises a sequence of arrivals of said SFQ pulses, wherein arrival times within said sequence of arrival times are determined at least in part by said SFQ pulse clock, and wherein a length of said sequence of arrival times is determined at least in part by a number of periods of said SFQ pulse clock frequency. In some embodiments, said off-ramp part is a reversed copy of said on-ramp part.

In some embodiments, (ii) comprises selecting said on-ramp part, said off-ramp part, and a length of said resonant part of said at least one SFQ pulse schedule based at least in part on a figure of merit of said one or more target single-qubit gates. In some embodiments, said figure of merit comprises an average of said figures of merit of a plurality of said target single-qubit gates. In some embodiments, said figure of merit comprises an average of said figures of merit of a plurality of qubits.

In some embodiments, said on-ramp part and said off-ramp part are substantially identical for a plurality of said target single-qubit gates. In some embodiments, said on-ramp part and said off-ramp part are substantially identical for a plurality of qubits of said one or more qubits.

In another aspect, the present disclosure provides a system for scheduling single flux quantum (SFQ) pulses of a qubit. The system may comprise: (a) a quantum computer controlled by SFQ control electronics having (i) a quantum chip comprising one or more qubits, and (ii) a control/readout system; and (b) a digital computer communicatively coupled to said quantum computer, said digital computer comprising a processor and a memory with instructions stored thereon which when executed by the processor are configured to at least: (i) obtain at least one SFQ pulse schedule for said one or more qubits, wherein said at least one schedule comprises an on-ramp part, a resonant part, and an off-ramp part; and (ii) instruct said quantum computer to implement said at least one SFQ pulse schedule for said one or more qubits.

In some embodiments, at (i) the processor is further configured to: (1) obtain an indication of a target single-qubit gate having a target angle; (2) obtain a frequency and an anharmonicity of a qubit of said one or more qubits; (3) obtain a frequency of an SFQ pulse clock; (4) scheduling arrivals of single flux quantum (SFQ) pulses; (5) obtain an SFQ kick angle; (6) identify a group of potential SFQ pulse schedules; (7) compare an implemented gate to said target single-qubit gate; and (8) select said at least one SFQ pulse schedule.

In some embodiments, said quantum computer is coupled to and cooled by a cryogenic device at a desired cryogenic temperature, wherein said cryogenic device comprises different cryogenic stages at different cryogenic temperatures; and further wherein said SFQ control electronics are coupled to and cooled by said cryogenic device at a said different cryogenic stage.

In some embodiments, said one or more qubits are superconducting qubits. In some embodiments, said superconducting qubits comprise transmon qubits or fluxonium qubits.

In some embodiments, at (i) the processor is further configured to: (1) obtain an indication of one or more target single-qubit gates each having a target angle; and (2) use an optimization protocol to select said at least one SFQ pulse schedule, wherein said optimization protocol uses said one or more target single-qubit gates and said frequency. In some embodiments, at (i) the processor is further configured to: (3) obtain properties of said system of said one or more qubits allowing for simulation of a quantum state of said system of said one or more qubits using a digital computer; (4) obtain an indication of an SFQ pulse effect on said system of said one or more qubits; (5) obtain said frequency of said SFQ pulse clock; and (6) schedule arrivals of said SFQ pulse; wherein said optimization protocol comprises simulating a quantum state of said one or more qubits using said digital computer. In some embodiments, at (2) the processor is further configured to: (a) select a group of SFQ pulse schedules, wherein each SFQ pulse schedule in said group comprises on-ramp, resonant, and off-ramp parts; (b) provide said each SFQ pulse schedule in said group to said one or more qubits; (c) perform a group of experiments, wherein each experiment comprises: initializing a quantum state of said one or more qubits using said each SFQ pulse schedule one or more times, and performing a quantum state measurement to obtain results; and (d) compare said results obtained in (c) to expected results of said one or more target single-qubit gates to select at least one SFQ pulse schedule.

In some embodiments, said optimization protocol comprises at least one member of the group consisting of: exhaustive search, gradient based optimization, gradient-free optimization, genetic algorithms, reinforcement learning, machine learning, heuristics for limiting the search space, tree search, and manual search. In some embodiments, said properties of said system of said one or more qubits comprise: properties of individual qubits and properties of interactions between said one or more qubits. In some embodiments, said indication of said SFQ pulse effect on said system of said one or more qubits comprises a kick angle, wherein said kick angle comprises a rotation angle of a quantum state of a qubit in a Hilbert space resulting from an SFQ pulse. In some embodiments, said properties of said system of said one or more qubits comprise a frequency and an anharmonicity of each of said one or more qubits.

In some embodiments, said on-ramp part comprises a sequence of arrivals of said SFQ pulse, wherein arrival times within said sequence of arrival times are determined at least in part by said SFQ pulse clock, and wherein a length of said sequence is determined at least in part by a number of periods of said SFQ pulse clock frequency. In some embodiments, said resonant part comprises a resonant pulse train comprising a pattern of arrivals of SFQ pulses, wherein said pattern of arrivals repeats at about a qubit frequency. In some embodiments, said off-ramp part comprises a sequence of arrivals of said SFQ pulses, wherein arrival times within said sequence of arrival times are determined at least in part by said SFQ pulse clock, and wherein a length of said sequence of arrival times is determined at least in part by a number of periods of said SFQ pulse clock frequency. In some embodiments, said off-ramp part is a reversed copy of said on-ramp part.

In some embodiments, at (2) the processor is further configured to: select said on-ramp part, said off-ramp part, and a length of said resonant part of said at least one SFQ pulse schedule based at least in part on a figure of merit of said one or more target single-qubit gates. In some embodiments, said figure of merit comprises an average of said figures of merit of a plurality of said target single-qubit gates. In some embodiments, said figure of merit comprises an average of said figures of merit of a plurality of qubits. In some embodiments, said on-ramp part and said off-ramp part are substantially identical for a plurality of said target single-qubit gates. In some embodiments, said on-ramp part and said off-ramp part are substantially identical for a plurality of qubits of said one or more qubits.

In another aspect, the present disclosure provides a system for scheduling single flux quantum (SFQ) pulses of a qubit. The system may comprise: (a) a digital computer communicatively coupled to a quantum computer controlled by SFQ control electronics having (i) a quantum chip comprising one or more qubits, and (ii) a control/readout system, wherein said digital computer comprises a processor and a memory with instructions stored thereon which when executed by the processor are configured to at least: (i) obtain at least one SFQ pulse schedule for said one or more qubits, wherein said at least one schedule comprises an on-ramp part, a resonant part, and an off-ramp part; and (ii) instruct said quantum computer to implement said at least one SFQ pulse schedule for said one or more qubits.

In another aspect, the present disclosure provides a system for scheduling single flux quantum (SFQ) pulses of a qubit. The system may comprise: a quantum computer controlled by SFQ control electronics having (i) a quantum chip comprising one or more qubits, and (ii) a control/readout system, wherein said quantum computer is communicatively coupled to a digital computer, said digital computer comprising a processor and a memory with instructions stored thereon which when executed by the processor are configured to at least: (i) obtain at least one SFQ pulse schedule for said one or more qubits, wherein said at least one schedule comprises an on-ramp part, a resonant part, and an off-ramp part; and (ii) instruct said quantum computer to implement said at least one SFQ pulse schedule for said one or more qubits.

In another aspect, the present disclosure provides a method for controlling a system of superconducting qubits using single flux quantum (SFQ) pulse schedule comprising on-ramp, off-ramp, and resonant parts, wherein frequency of single flux quantum (SFQ) clock is at about a multiple of a qubit frequency. The method comprises providing a system of qubits; delivering a single flux quantum (SFQ) pulse to each qubit, the single flux quantum (SFQ) pulse capable of influencing a quantum state of a qubit; obtaining at least one single flux quantum (SFQ) pulse schedule for one or more qubits, each schedule comprising on-ramp, resonant and off-ramp parts; implementing said at least one single flux quantum (SFQ) pulse schedule to said one or more qubits.

In some embodiments, said superconducting qubits comprise transmon qubits or fluxonium qubits.

In some embodiments, obtaining at least one single flux quantum (SFQ) pulse schedule for one or more qubits comprises obtaining one or more target single-qubit gates each having a target angle; using an optimization protocol to select at least one single flux quantum (SFQ) schedule, wherein said optimization protocol uses said one or more target single-qubit gates and said frequency.

In some embodiments, the method further comprises obtaining properties of said system of qubits allowing for simulation of a quantum state of said system of qubits using a digital computer; obtaining an indication of single flux quantum (SFQ) pulse effect on said system of qubits; obtaining frequency of a clock scheduling arrivals of the single flux quantum (SFQ) pulses; wherein said optimization protocol comprises simulating a quantum state of said system of qubits using a digital computer.

In some embodiments, said using an optimization protocol to select at least one single flux quantum (SFQ) schedule comprises selecting a group of single flux quantum (SFQ) schedules each comprising on-ramp, resonant and off-ramp parts; providing each said single flux quantum (SFQ) schedule in said group to said one or more qubits; and performing a group of experiments each experiment comprising quantum state initialization of one or more qubits, using said single flux quantum (SFQ) schedule one or more times, and performing quantum state measurement to obtain results; and comparing said obtained results to the expected results of said one or more single-qubit target gates to select at least one single flux quantum (SFQ) schedule.

In some embodiments, said optimization protocol comprises at least one member of the group consisting of: exhaustive search, gradient based optimization, gradient free optimization, genetic algorithm, reinforcement learning, machine learning, heuristics for limiting the search space, tree search, and manual search.

In some embodiments, said properties of said system of qubits comprise properties of individual qubits and properties of interactions between said qubits.

In some embodiments, said effect on said system of qubits comprises kick angle, wherein said kick angle comprises rotation angle of the quantum state of a qubit in Hilbert space resulting from a single flux quantum (SFQ) pulse.

In some embodiments, said properties of said system of qubits comprise frequency and anharmonicity of each said qubit.

In some embodiments, said schedules of single flux quantum (SFQ) pulses have three independent parts: (i) said on-ramp part is a sequence of arrivals of said single flux quantum (SFQ) pulses, wherein possible arrival times are determined by a single flux quantum (SFQ) pulses clock, and the sequence's length is determined by a certain number of periods of a single flux quantum (SFQ) clock frequency (ii) said resonant part is a resonant pulse train comprising a pattern of arrivals of SFQ pulses, which pattern repeats at about a qubit frequency; and (iii) said off-ramp is a sequence of arrivals of said single flux quantum (SFQ) pulses, wherein possible arrivals are determined by said single flux quantum (SFQ) pulses clock, and the sequence's length is determined by a certain number of periods of said single flux quantum (SFQ) clock frequency.

In some embodiments, said off-ramp part is a reversed copy of said on-ramp part.

In some embodiments, said obtaining at least one single flux quantum (SFQ) pulse schedule for one or more qubits comprises selecting said on-ramp, off-ramp parts and the length of said resonant part of the schedule using a figure of merit of said single-qubit target gate. In some embodiments, said figure of merit comprises average of figures of merit of a plurality of single-qubit target gates. In some embodiments, said figure of merit comprises average of figures of merit of a plurality of qubits.

In some embodiments, said on-ramp and off-ramp parts are identical for a plurality of single-qubit target gates.

In some embodiments, said on-ramp and off-ramp parts are identical for a plurality of qubits.

Another aspect of the present disclosure provides a system for a system for scheduling single flux quantum (SFQ) pulses of a qubit. The system comprises a quantum computer with SFQ control electronics having (i) a quantum chip comprising one or more qubits, and (ii) a control/readout system; a digital computer operatively coupled to the quantum computer, the digital computer comprising a memory having instructions to at least obtain at least one single flux quantum (SFQ) pulse schedule for one or more qubits, each schedule comprising on-ramp, resonant and off-ramp parts; and instruct said quantum computer to implement said at least one single flux quantum (SFQ) pulse schedule to said one or more qubits. In some embodiments, the instructions comprise obtaining a target single-qubit gate having a target angle, obtaining frequency and anharmonicity of a qubit, obtain frequency of a clock scheduling arrivals of single flux quantum (SFQ) pulses, obtaining a single flux quantum (SFQ) kick angle, identifying a group of potential single flux quantum (SFQ) schedules, comparing an implemented gate to a target gate, instruct said quantum computer to implement a gate.

Another aspect of the present disclosure provides a system comprising one or more computer processors and computer memory coupled thereto. The computer memory comprises machine executable code that, upon execution by the one or more computer processors, implements any of the methods disclosed above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 is a schematic of an example of a system for controlling a system of superconducting qubits using a single flux quantum (SFQ) pulse schedule comprising on-ramp, off-ramp, and resonant parts, in accordance with some embodiments disclosed herein.

FIG. 2 is a flowchart of an example of a method for controlling a system of superconducting qubits using an SFQ pulse schedule comprising on-ramp, off-ramp, and resonant parts, in accordance with some embodiments disclosed herein.

FIG. 3 is a flowchart of an example of a procedure for obtaining at least one SFQ pulse schedule for one or more qubits, in accordance with some embodiments disclosed herein.

FIG. 4 is a flowchart of an example of a procedure for using an optimization protocol to select at least one SFQ pulse schedule, in accordance with some embodiments disclosed herein.

### DETAILED DESCRIPTION

While various embodiments of the invention are shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Neither the Title nor the Abstract is to be taken as limiting in any way the scope of the disclosed invention(s). The title of the present application and headings of sections provided in the present application are for convenience only and are not to be taken as limiting the disclosure in any way.

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

The term “plurality” generally refers to “two or more,” unless expressly specified otherwise.

The term “e.g.” and like terms mean “for example,” and thus do not limit the terms or phrases they explain. For example, in a sentence “the computer sends data (e.g., instructions, a data structure) over the Internet,” the term “e.g.” explains that “instructions” are an example of “data” that the computer may send over the Internet, and also explains that “a data structure” is an example of “data” that the computer may send over the Internet. However, both “instructions” and “a data structure” are merely examples of “data,” and other things besides “instructions” and “a data structure” can be “data.”

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

Where values are described as ranges, the disclosure includes the disclosure of all possible sub-ranges within such ranges, as well as specific numerical values that fall within such ranges irrespective of whether a specific numerical value or specific sub-range is expressly stated.

Certain inventive embodiments herein contemplate numerical ranges. When ranges are present, the ranges include the range endpoints. Additionally, every sub-range and value within the range is present as if explicitly written out.

The term “about” or “approximately” may mean within an acceptable error range for the particular value, which will depend in part on how the value is measured or determined, e.g., the limitations of the measurement system. For example, “about” may mean within 1 or more than 1 standard deviation, per the practice in the art. Alternatively, “about” may mean a range of up to 20%, up to 10%, up to 5%, or up to 1% of a given value. Where particular values are described in the application and claims, unless otherwise stated the term “about” meaning within an acceptable error range for the particular value may be assumed.

### Quantum Computing

Quantum computing may be a method of computing which utilizes the concept of quantum superposition and entanglement to manipulate information. By contrast, classical computers may use the binary bits 0 and 1. Quantum entanglement may be phenomenon in which, when multiple qubits interact with each other, their quantum states are “entangled” and may no longer be represented individually. Quantum superposition may be the principle which states that the quantum state of a qubit can be represented by adding together two or more different quantum states, each associated with a probability. In some cases, the probabilities of all states add to 1. Quantum circuits, consisting of one or more quantum gates, may be designed to perform quantum computation, such as factoring large prime numbers, which may be infeasible or highly inefficient for classical computers. Quantum gates may comprise logical operators comprising one or multiple qubits, which can be used to perform logical operations.

In contrast to quantum computing, classical computation may be computation performed using binary values using discrete bits without use of quantum mechanical superposition and quantum mechanical entanglement. A classical computer may be a digital computer, such as a computer employing discrete bits (e.g., 0s and 1s) without use of quantum mechanical superposition and quantum mechanical entanglement. A non-classical computer may comprise any method or system for performing computational procedures outside of the paradigm of classical computing.

A quantum device may be any device or system for performing computations using any quantum mechanical phenomenon such as quantum mechanical superposition and quantum mechanical entanglement. Quantum computations, quantum procedures, quantum operations, and quantum computers described herein may comprise any method or system for performing computations using quantum mechanical operations (such as unitary transformations or completely positive trace-preserving (CPTP) maps on quantum channels) on a Hilbert space represented by a quantum device. A quantum chip may be a physical device that can utilize quantum phenomena that allows the execution of quantum gates for the purpose of computing.

A qubit, short for quantum bit, may be the basic unit of quantum information. A qubit may comprise quantum states comprising a complex unit vector of dimension 2. These two dimensions may be referred to as “0” and “1.” A physical qubit may be a physical implementation of a qubit. For example, a superconducting qubit may be a physical qubit implemented using superconducting electronic circuits.

A quantum gate operation may comprise a quantum gate, a sequence of quantum gates or a combination of quantum gates and quantum measurements that perform an isometry on the quantum state of qubits. Gates, two-qubit gates, and one-qubit gates may comprise quantum logic gates which are used to perform logical operations. A two-qubit gate may consist of two qubits. A one-qubit gate may consist of one qubit. A quantum chip may comprise a physical device that can utilize quantum phenomena that allows the execution of quantum gates for the purpose of computing.

A circuit may comprise the representation of a computational model in which the computation comprises a sequence of gates. In some cases, a circuit may be used in gate model quantum computation. In some cases, a circuit may be a quantum circuit, such as a sequence of qubit gates used in a gate model quantum computation. A quantum circuit may comprise an initial state preparation for a set of qudits, followed by performing a gate operation and measurements on it. A quantum measurement may comprise a process for extracting classical information from quantum states generated on quantum devices. Quantum computing devices may use quantum gates. A quantum gate may be a manipulation of qubits that can be represented by unitary operation on the quantum state of the qubits. A quantum gate operation may comprise a quantum gate, a sequence of quantum gates or a combination of quantum gates and quantum measurements that perform an isometry on the quantum state of qubits. For example, gates, two-qubit gates, and one-qubit gates may be used to perform logical operations. A one-qubit gate may comprise one qubit. A two-qubit gate may comprise two qubits.

### Single Flux Quantum (SFQ) Technology

Accurate quantum control may be useful for reliable quantum computing. One possible architecture is superconducting quantum computers that make use of Josephson qubits. One challenge to building large-scale superconducting quantum computers is related to quantum control, such as sending accurate microwave signals to control thousands of qubits, reducing the number of required control wires, etc. Another challenge is related to the wiring heat load.

A single-flux quantum (SFQ) may be a single quantum of magnetic flux. Magnetic flux may be generated using an electronic device that uses one or more Josephson junctions to generate and/or process digital signals. The SFQ-based control technique is a digital approach to resolving issues of scalability related to the standard control of quantum systems, such as physical space and heat. It has been proposed and experimentally demonstrated in McDermott et al., “Accurate Qubit Control with Single Flux Quantum Pulses,” Physical Review Applied: 2, 014007, 2014, which is incorporated by reference herein in its entirety). SFQ control may be a control technique that utilizes single-flux quanta for control.

SFQ electronics have been introduced to mitigate problems such as reducing the number of control wires or heat load. SFQ pulses may enable the digital control of qubits by using fluxons in superconducting qubits. The accuracy of SFQ-based control may be due in part to the fact that time integration of a voltage pulse has a quantized value h/2e, where h is a Planck constant and e is an electric charge. Furthermore, an SFQ technology is cryogenic, which may address at least some of the problems resulting from heat load from control wiring as well as the number of required wires and is also in situ. References on the status of SFQ technology in quantum computing include McDermott et al., “Accurate Qubit Control with Single Flux Quantum Pulses,” Physical Review Applied 2, 014007, 2014 and Li et al., “Hardware-Efficient Qubit Control with Single-Flux-Quantum Pulse Sequences,” Physical Review Applied 12, 014044, 2019, each of which is incorporated herein by reference in its entirety.

SFQ technologies may be a family of superconducting electronics technologies. The family of superconducting electronics technologies may comprise electronic circuits containing Josephson junctions. The electronic circuits may be capable of processing classical information which may be expressed through the presence or absence of SFQ pulses in the circuit. An SFQ pulse may be a voltage pulse produced in SFQ electronics. The voltage pulse may be produced when the magnetic flux of a superconducting loop containing a Josephson junction changes by one flux quantum Φ₀. An SFQ pulse may have a duration of a few picoseconds and a temporal voltage integral of one flux quantum Φ₀. An SFQ pulse schedule may be a temporal sequence of SFQ pulses. An SFQ pulse schedule may have a specified total duration. An SFQ pulse schedule may contain a specified number of SFQ pulses. Each SFQ pulse contained in the SFQ pulse schedule may have a specified arrival time.

Examples of superconducting SFQ logic are disclosed, for example, in Leonard Jr. et al., “Digital Coherent Control of a Superconducting Qubit,” Physical Review Applied 11, 014009, 2019; Liebermann et al., “Optimal Qubit Control Using Single-Flux Quantum Pulses,” Physical Review Applied 6, 024022, 2016; Johnson et al., “A scalable control system for a superconducting adiabatic quantum optimization processor,” Superconductor Science and Technology 23, 065004, 2010; and Li et al., “Hardware-Efficient Qubit Control with Single-Flux-Quantum Pulse Sequences,” Physical Review Applied 12, 014044, 2019; each of which is incorporated by reference in its entirety.

Accurate quantum control may be advantageous for quantum computing applications. An example architecture is superconducting quantum computers, which use Josephson junction-based qubits. Quantum control may be a challenge to building large scale superconducting quantum computers. Examples of existing challenges may include sending accurate microwave signals to control thousands of qubits and reducing the number of required control wires as well as wiring heat load, etc.

As disclosed elsewhere herein, an SFQ pulse may be introduced to mitigate these problems. It may enable the control of qubits digitally by using fluxons in superconducting circuits. In some cases, the time integration of a voltage pulse has a quantized value h/2e, where h is a Planck constant and e is an electric charge. Furthermore, SFQ technology is in situ and cryogenic, which resolves the problems of heat load from control wires as well as the number of required wires.

For example, a system described in WO 2022/125186, which is incorporated by reference in its entirety, presents a modular design with an SFQ-based control module physically split from the quantum chip. In some cases, the classical and quantum modules may be located on separate physical chips flip-chip bonded to each other with the help of indium bumps. The communication of classical control and readout signals may be performed via capacitive couplings between the modules. One of the functions of the classical module may be to convert these signals to and from SFQ pulse sequences in order to facilitate their digital processing.

Superconducting qubits using SFQ technology may show promise for overcoming control scaling issues. (See, for example, McDermott et al., “Quantum-classical interface based on single flux quantum digital logic,” Quantum Science and Technology 3, 024004, 2018; McDermott et al., “Accurate Qubit Control with Single Flux Quantum Pulses,” Physical Review Applied 2, 014007, 2014; Liebermann et al., “Optimal Qubit Control Using Single-Flux Quantum Pulses,” Physical Review Applied 6, 024022, 2016; Leonard Jr. et al., “Digital Coherent Control of a Superconducting Qubit,” Physical Review Applied 11, 014009, 2019; Li et al., “Hardware-Efficient Qubit Control with Single-Flux-Quantum Pulse Sequences,” Physical Review Applied 12, 014044, 2019; Jokar et al., “DigiQ: A scalable digital controller for quantum computers using SFQ logic,” in 2022 IEEE International Symposium on High-Performance Computer Architecture (HPCA), pp. 400-414, IEEE, 2022; Dalgaard et al., “Global Optimization of Quantum Dynamics with AlphaZero Deep Exploration,” npj Quantum Information 6, no. 6, 2020; and Mukhanov et al., “Scalable quantum computing infrastructure based on superconducting electronics,” in 2019 IEEE International Electron Devices Meeting (IEDM), pp. 31-2, IEEE, 2019; each of which is incorporated herein by reference for all purposes.) In the SFQ-based approach, control signals may be generated by an SFQ co-processor, co-located with the qubits in a cryostat, thereby reducing analog control lines.

Despite the potential for overcoming control scaling issues, there may be practical limitations on the power consumed and the footprint occupied by SFQ electronics. Without being limited by theory, SFQ pulse sequences may be described by few bits of data and the SFQ circuit generating the complete sequence from such data may be simplified in order to mitigate the power consumption and the footprint. At the same time, it may be advantageous for the quality of qubit control to be comparatively high, for example, at least comparable to microwave control systems, to allow for large-scale quantum computation.

In addition, it may be desirable to have access to implementations of many high-quality single-qubit basis gates for each qubit, to facilitate the decomposition (at least approximate) of an arbitrary single-qubit gate into a small number of basis gates. Therefore, it may be desirable to develop a large set of SFQ control sequences for each qubit, while keeping the demands on the control electronics low. In some cases, in microwave qubit control, a continuous family of virtual Z gates may be implemented by adjusting the phase relative to the qubit oscillations of later drives, and single-qubit gates may be efficiently decomposed using virtual Z gates if one suitable additional gate is available. However, in SFQ-based control, this solution may not be available, because SFQ pulse sequences may be restricted to be aligned with a fixed clock which may limit free shifting of the phase by fractional amounts.

An SFQ control sequence may be a pulse sequence which is resonant or sub-resonant with the qubit frequency. (See, for example, McDermott et al., “Quantum-classical interface based on single flux quantum digital logic,” Quantum Science and Technology 3, 024004, 2018; McDermott et al., “Accurate Qubit Control with Single Flux Quantum Pulses,” Physical Review Applied 2, 014007, 2014; and Leonard Jr. et al., “Digital Coherent Control of a Superconducting Qubit,” Physical Review Applied 11, 014009, 2019; each of which is incorporated by reference in its entirety.) This approach may generate a single-qubit average gate fidelity of 95% (obtained with randomized benchmarking), demonstrating the viability of SFQ-based qubit control. While this approach can be implemented with simple electronics and allows for a large set of single-qubit gates by varying the length of the pulse sequence, the fidelity of the resulting gates may be insufficient for large-scale quantum computation. In some cases, the fidelity of the resulting gates may be insufficient due to leakage.

While simulations might find that good gate fidelities may be reached by using optimization methods to find SFQ control sequences, restricting the sequences by demanding that SFQ pulses align with a clock, there may be technical barriers to physical implementation. Simulations may be found in, for example, McDermott et al., “Quantum—classical interface based on single flux quantum digital logic,” Quantum Science and Technology 3, 024004, 2018; and Liebermann et al., “Optimal Qubit Control Using Single-Flux Quantum Pulses,” Physical Review Applied 6, 024022, 2016; Dalgaard et al., “Global Optimization of Quantum Dynamics with AlphaZero Deep Exploration,” npj Quantum Information 6, no. 6, 2020; each of which is incorporated by reference in its entirety. The sequences arising from such approaches may, in some cases, show little structure. Without being limited by theory, low-power and low-footprint SFQ control electronics which generate these sequences may be difficult to develop. Furthermore, performing a different gate on the same qubit, or the same gate on a different qubit, may require the use of an additional control sequence, which may pose challenges for calibration and further increase the demands on the complexity of the control system.

It may be determined by simulations that implementing qubit rotations by a small angle and delivering those sequences to the qubit repeatedly in order to implement larger rotations reduce the complexity of the sequences compared to implementing larger rotations directly, because the sequences required for small rotations are shorter. A theoretical proposal of a particular implementation of this idea is given in Li et al., “Hardware-Efficient Qubit Control with Single-Flux-Quantum Pulse Sequences,” Physical Review Applied 12, 014044, 2019, which is incorporated by reference herein in its entirety. However, the control complexity may still be challenging in practice, considering that many separate sequences may be used to reach high-fidelity universal single-qubit control with acceptable overhead using the procedure.

### NISQ Technology—Noisy Intermediate-Scale Quantum Technology

The term “noisy, intermediate-scale quantum” (NISQ) was introduced in Preskill, “Quantum Computing in the NISQ era and beyond,” arXiv: 1801.00862, 2018, which is incorporated herein by reference in its entirety. Here, the term “noisy” implies that there may be incomplete control over the qubits, and “intermediate-scale” refers to the number of qubits, which, in some cases, may range from about 50 to about a few hundred. Several physical systems made from superconducting qubits, artificial atoms, or ion traps have been proposed thus far as feasible candidates to build NISQ devices and, ultimately, universal quantum computers.

Methods and systems disclosed herein may be suitable for a NISQ device. In some cases, a NISQ device with a limitation of a two-dimensional structure of a quantum chip or a limitation on how many neighboring qubits each qubit is connected to may benefit from methods and systems disclosed herein.

### Quantum Device/Quantum Hardware

Any type of non-classical computer, for example, a quantum computer, may be suitable for the technologies disclosed herein. In some cases, a quantum device with a limitation of a two-dimensional structure of a quantum chip or a limitation on how many neighboring qubits each qubit is connected to may benefit from methods and systems disclosed herein. In accordance with the description herein, suitable quantum computers may include, by way of non-limiting examples: superconducting quantum computers (qubits implemented as small superconducting circuits Josephson junctions) (Clarke et al., “Superconducting quantum bits,” Nature 453, no. 7198, pp. 1031-1042, 2008); trapped-ion quantum computers (qubits implemented as states of trapped ions) (Kielpinski et al., “Architecture for a large-scale ion-trap quantum computer,” Nature 417, no. 6890, pp. 709-711, 2002); optical lattice quantum computers (qubits implemented as states of neutral atoms trapped in an optical lattice) (Deutsch et al., “Quantum computing with neutral atoms in an optical lattice,” Fortschritte der Physik: Progress of Physics 48, no. 9-11, pp. 925-943, 2000); spin-based quantum dot computers (qubits implemented as the spin states of trapped electrons) (Imamoğlu et al., “Quantum information processing using quantum dot spins and cavity QED,” Physical Review Letters 83, no. 20, p. 4204, 1999); spatial-based quantum dot computers (qubits implemented as electron positions in a double quantum dot) (Fedichkin et al., “Novel coherent quantum bit using spatial quantization levels in semiconductor quantum dot,” arXiv: quant-ph/0006097, 2000); coupled quantum wires (qubits implemented as pairs of quantum wires coupled by quantum point contact) (Bertoni et al., “Quantum logic gates based on coherent electron transport in quantum wires,” Physical Review Letters 84, no. 25, p. 5912, 2000); nuclear magnetic resonance quantum computers (qubits implemented as nuclear spins and probed by radio waves) (Cory et al., “Nuclear magnetic resonance spectroscopy: An experimentally accessible paradigm for quantum computing,” arXiv: quant-ph/9709001, 1997); solid-state NMR Kane quantum computers (qubits implemented as the nuclear spin states of phosphorus donors in silicon) (Kane, “A silicon-based nuclear spin quantum computer,” Nature 393, no. 6681, pp. 133-137, 1998); electrons-on-helium quantum computers (qubits implemented as electron spins) (Lyon, “Spin-based quantum computing using electrons on liquid helium,” arXiv: cond-mat/0301581, 2006); molecular magnet-based quantum computers (qubits implemented as spin states) (Leuenberger et al., “Quantum Computing in Molecular Magnets,” arXiv: cond-mat/0011415, 2001); fullerene-based ESR quantum computers (qubits implemented as electronic spins of atoms or molecules encased in fullerenes) (Harneit, “Spin Quantum Computing with Endohedral Fullerenes,” arXiv: 1708.09298, 2017); diamond-based quantum computers (qubits implemented as electronic or nuclear spins of nitrogen-vacancy centres in diamond) (Nizovtsev et al., “A quantum computer based on NV centers in diamond: optically detected nutations of single electron and nuclear spins,” Optics and spectroscopy 99, no. 2, pp. 233-244, 2005); Bose-Einstein condensate-based quantum computers (qubits implemented as two-component BECs) (Byrnes et al., “Macroscopic quantum computation using Bose-Einstein condensates,” arXiv: quantum-ph/1103.5512, 2011); transistor-based quantum computers (qubits implemented as semiconductors coupled to nanophotonic cavities) (Sun et al., “A single-photon switch and transistor enabled by a solid-state quantum memory,” arXiv: quant-ph/1805.01964, 2018); metal-like carbon nanospheres based quantum computers (qubits implemented as electron spins in conducting carbon nanospheres) (Náfrádi et al., “Room temperature manipulation of long lifetime spins in metallic-like carbon nanospheres,” arXiv: cond-mat/1611.07690, 2016); topological quantum computers (qubits implemented as non-Abelian anyons) (Nayak et al., “Non-Abelian Anyons and Topological Quantum Computation,” arXiv: 0707.1889, 2007); photonic continuous-variable quantum computing hardware (quantum variables represented by the quadrature operators of the quantum harmonic oscillators in a quantum optical mode) (Arrazola et al., “Quantum circuits with many photons on a programmable nanophotonic chip,” Nature 591, pp. 54-60, 2021); photonic qubit-based quantum hardware (qubits implemented on pairs of optical paths) (O'Brien et al., “Photonic quantum technologies,” Nature Photonics 3, pp. 687-695, 2009); quantum computing hardware based on bosonic codes (error-protected qubits are formed by embedding a finite-dimensional code space within the infinite-dimensional Fock space associated with a bosonic quantum field mode; examples include the Gottesman-Kitaev-Preskill (GKP) code, cat codes, and binomial codes, respectively) (Gottesman et al., “Encoding a qubit in an oscillator,” Physical Review A 64, 012310, 2001; Chamberland et al., “Building a Fault-Tolerant Quantum Computer Using Concatenated Cat Codes,” PRX Quantum 3, 010329, 2022; Michael et al., “New Class of Quantum Error-Correcting Codes for a Bosonic Mode,” Physical Review X 6, 031006, 2016); quantum hardware based on coherent network computing (operating by sampling low-energy eigenstates of an Ising Hamiltonian by encoding the spins in a network of optical parametric oscillators with all-to-all connectivity; future architectures may exploit quantum entanglement for computation) (Inui et al., “Entanglement and quantum discord in optically coupled coherent Ising machines,” Physical Review A 102, 062419, 2020; and Yanagimoto et al., “Embedding entanglement generation within a measurement-feedback coherent Ising machine,” arXiv: 1906.04902, 2019); each of which is incorporated herein by reference in its entirety.

### Digital Computer

In some cases, a digital computer comprises one or more hardware central processing units (CPUs) that carry out a classical computer's functions. In some cases, the classical computer further comprises an operating system (OS) configured to perform executable instructions. In some cases, the classical computer is connected to a computer network. In some cases, the classical computer is connected to the Internet such that it accesses the World Wide Web. In some cases, the classical computer is connected to a cloud computing infrastructure. In some cases, the classical computer is connected to an intranet. In some cases, the classical computer is connected to a data storage device.

In accordance with the description herein, suitable classical computers may include, by way of non-limiting examples, server computers, desktop computers, laptop computers, notebook computers, sub-notebook computers, netbook computers, netpad computers, set-top computers, media streaming devices, handheld computers, Internet appliances, mobile smartphones, tablet computers, personal digital assistants, video game consoles, and vehicles. Smartphones may be suitable for use with methods and systems described herein. Select televisions, video players, and digital music players, in some cases, with computer network connectivity, may be suitable for use in the systems and methods described herein. Suitable tablet computers may include those with booklet, slate, and convertible configurations.

In some cases, the classical computer includes an operating system configured to perform executable instructions. The operating system may be, for example, software, including programs and data, which manages the device's hardware and provides services for execution of applications. Suitable server operating systems include, by way of non-limiting examples, FreeBSD, OpenBSD, NetBSD®, Linux®, Apple Mac OS X Server®, Oracle® Solaris®, Windows Server®, and Novell® NetWare®. Suitable personal computer operating systems may include, by way of non-limiting examples, Microsoft® Windows®, Apple Mac OS X®, Apple® macOS®, UNIX®, and UNIX-like operating systems such as GNU/Linux®. In some cases, the operating system is provided by cloud computing. Suitable mobile smart phone operating systems may include, by way of non-limiting examples, Nokia® Symbian® OS, Apple® iOS®, Research In Motion® BlackBerry OS®, Google® Android®, Microsoft® Windows Phone® OS, Microsoft Windows Mobile® OS, Linux®, and Palm® WebOS®. Suitable media streaming device operating systems may include, by way of non-limiting examples, Apple TV®, Roku®, Boxee®, Google TV®, Google Chromecast®, Amazon Fire®, and Samsung® HomeSync®. Suitable video game console operating systems may include, by way of non-limiting examples, Sony® PS3®, Sony® PS4®, Microsoft® Xbox 360®, Microsoft Xbox One®, Nintendo® Wii®, Nintendo® Wii U®, and Ouya®.

In some cases, the classical computer includes a storage and/or memory device. In some cases, the storage and/or memory device is one or more physical apparatuses used to store data or programs on a temporary or permanent basis. In some cases, the storage and/or memory device may have one or more additional data storage units that are external to the classical computer, for example, being located on a remote server that is in communication with the classical computer through an intranet or the Internet. In some cases, the device comprises a volatile memory and requires power to maintain stored information. In some cases, the device comprises non-volatile memory and retains stored information when the classical computer is not powered. In some cases, the non-volatile memory comprises flash memory. In some cases, the non-volatile memory comprises dynamic random-access memory (DRAM). In some cases, the non-volatile memory comprises ferroelectric random-access memory (FRAM). In some cases, the non-volatile memory comprises phase-change random-access memory (PRAM). In some cases, the non-volatile memory comprises resistive random-access memory (RRAM). In some cases, the device comprises a storage device including, by way of non-limiting examples, CD-ROMs, DVDs, flash memory devices, magnetic disk drives, magnetic tapes drives, optical disk drives, and cloud computing-based storage. In some cases, the storage and/or memory device comprises a combination of devices such as those disclosed herein.

In some cases, the classical computer includes a display to send visual information to a user. In some cases, the display is a cathode ray tube (CRT). In some cases, the display is a liquid crystal display (LCD). In some cases, the display is a thin film transistor liquid crystal display (TFT-LCD). In some cases, the display is an organic light emitting diode (OLED) display. In some cases, on OLED display is a passive-matrix OLED (PMOLED) or active-matrix OLED (AMOLED) display. In some cases, the display is a plasma display. In some cases, the display is a video projector. In some cases, the display is a combination of devices such as those disclosed herein.

In some cases, the classical computer includes an input device to receive information from a user. In some cases, the input device is a keyboard. In some cases, the input device is a pointing device including, by way of non-limiting examples, a mouse, trackball, track pad, joystick, game controller, or stylus. In some cases, the input device is a touch screen or a multi-touch screen. In some cases, the input device is a microphone to capture voice or other sound input. In some cases, the input device is a video camera or other sensor to capture motion or visual input. In some cases, the input device is a Kinect®, Leap Motion®, or the like. In some cases, the input device is a combination of devices such as those disclosed herein.

In the following detailed description, reference is made to the accompanying figures, which form a part hereof. In the figures, similar symbols typically identify similar components, unless context dictates otherwise. The illustrative embodiments described in the detailed description, figures, and claims are not meant to be limiting. Other embodiments may be used, and other changes may be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

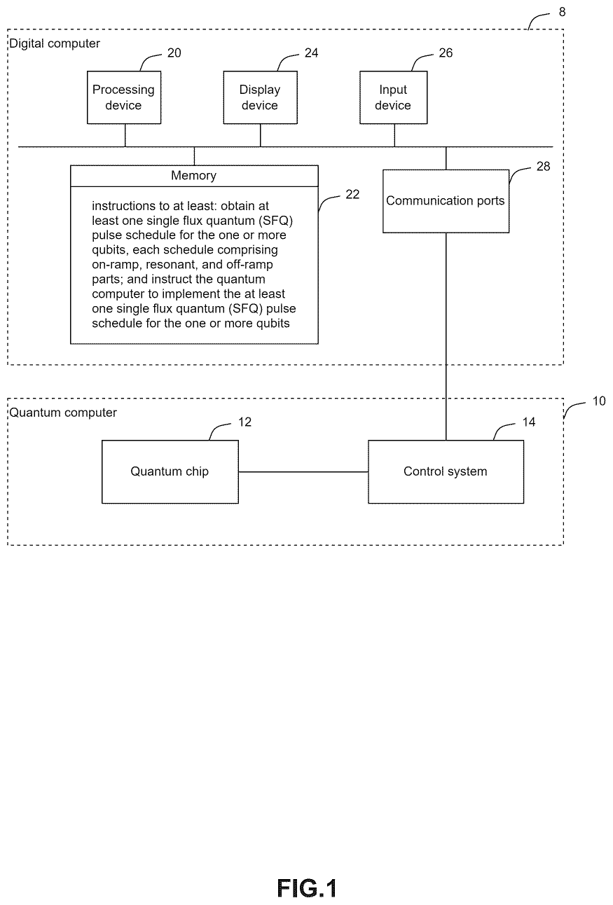

Now referring to FIG. 1, there is shown a schematic of an embodiment of a system for controlling a system of superconducting qubits using an SFQ pulse schedule comprising on-ramp, off-ramp, and resonant parts. The system comprises i) a classical computer which in this embodiment is a digital computer 8, and ii) a quantum computer 10. The digital computer 8 may be any digital computer disclosed elsewhere herein. An on-ramp and an off-ramp may each be a part of an SFQ pulse schedule. In some cases, an on-ramp precedes an off-ramp. A resonant part of an SFQ pulse schedule may be between an on-ramp and an off-ramp. In some cases, during a resonant part a pattern of arrivals of SFQ pulses is repeated. The period may be about the period of a qubit, about an integer multiple of the period of a qubit, etc.

The quantum computer 10 comprises a quantum chip 12. In some cases, the quantum computer 10 comprises a control system 14. The quantum computer 10 is operatively connected to the digital computer 8 by way of connection between the control system 14 and communication ports 28. The quantum computer 10 may comprise any quantum computer such as any quantum device or quantum hardware disclosed herein.

In some cases, the quantum chip 12 may be coupled to and cooled by a cryogenic device at a desired cryogenic temperature. The cryogenic device is not shown in the diagram. In some cases, the cryogenic device has different cryogenic stages at different cryogenic temperatures. The control system 14 may comprise SFQ control electronics. In some cases, the SFQ control electronics may be coupled to and cooled by the cryogenic device at a different cryogenic stage. The cryogenic stages may be capable of efficiently dissipating varying levels of heat. In some cases, the SFQ control electronics may be kept in the cryogenic device at a cryogenic temperature higher than that of the quantum chip 12, such as 100 mK, 600 mK, 3 K, or 4 K. In some cases, the SFQ control electronics may be kept in the cryogenic device at the same cryogenic stage as the quantum chip 12 and at the same cryogenic temperature (e.g., tens of mK).

The cryogenic device may be of various types. In some cases, the cryogenic device includes a cryogenic platform capable of reaching the required low temperature for the operation of qubits. In some cases, the cryogenic device includes a dilution refrigerator system with different cryogenic stages at different temperatures. In some cases, the cryogenic device includes a cryocooler system. In other cases, the cryogenic device includes an adiabatic demagnetization refrigerator.

Still referring to FIG. 1, in some cases, the quantum computer 10 may comprise a system such as, for example, the system disclosed in WO 2022/125186, which is incorporated by reference herein in its entirety. In some cases, the quantum computer may comprise a system of superconducting qubits. In some cases, the quantum computer may comprise qubits based in part on Josephson-junctions.

In some cases, the digital computer 8 is used to provide instructions to the quantum computer 10 using the communication ports 28 and the control system 14.

In some cases, the digital computer 8 comprises a processing device 20, a display device 24, an input device 26, communication ports 28, and a memory 22. The processing device 20, the display device 24, the input device 26, the communication ports 28, and the memory 22 may be of various types, such as any type disclosed elsewhere herein. The memory 22 comprises a computer program executable by the processing device 20. The communication ports 28 communicate with the quantum computer 10 via the control system 14. In some cases, the digital processing device is communicatively coupled to the quantum computer. In some cases, the digital processing device is operatively coupled to the quantum computer. The digital processing devices may be local to the quantum computer or connected to the quantum computer over a network. In some cases, the network is a cloud computing network. In some cases, the network is a distributed computing network.

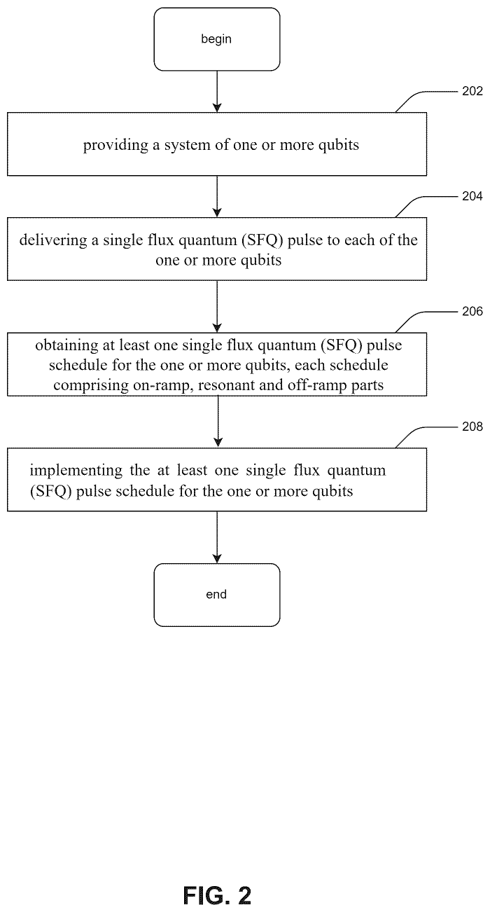

Now referring to FIG. 2, there is shown a flowchart of an embodiment of a method for controlling a system of superconducting qubits using an SFQ pulse schedule comprising on-ramp, off-ramp, and resonant parts.

According to processing operation 202, a system of one or more qubits is provided. The system of qubits may be provided in various ways. In some cases, the system is provided as a superconducting circuit fabricated on a silicon wafer, flip-chip bonded with a chip containing SFQ circuitry and installed in a dilution refrigerator. The qubits may be of various types. In some cases, the qubits are superconducting qubits such as fixed-frequency transmon qubits (see, for example, Koch et al., “Charge-insensitive qubit design derived from the Cooper pair box,” Physical Review A 76, 042319, 2007, which is incorporated by reference herein in its entirety), flux-tunable transmon qubits (see, for example, Koch et al., “Charge-insensitive qubit design derived from the Cooper pair box,” Physical Review A 76, 042319, 2007, which is incorporated by reference herein in its entirety), or fluxonium qubits (see, for example, Manucharyan et al., “Fluxonium: Single Cooper-Pair Circuit Free of Charge Offsets,” Science 326, pp. 113-116, 2009, which is incorporated by reference herein in its entirety). In some cases, the system of qubits comprises a single flux-tunable transmon qubit. In some cases, the system of qubits comprises several flux-tunable transmon qubits. In some cases, qubits are connected to each other with tunable coupling elements (see, for example, Yan et al., “Tunable coupling scheme for implementing high-fidelity two-qubit gates,” Physical Review Applied 10, 054062, 2018, which is incorporated by reference herein in its entirety). In some cases, the qubits are Kerr-cat qubits (see, for example, Mirrahimi et al., “Dynamically protected cat-qubits: a new paradigm for universal quantum computation,” New Journal of Physics 16, 045014, 2014, which is incorporated by reference herein in its entirety). In some cases, the qubits are one or several types of spin qubits (see, for example, Burkard et al., “Semiconductor Spin Qubits,” arXiv: 2112.08863, 2021, which is incorporated by reference herein in its entirety).

Still referring to FIG. 2 and according to processing operation 204, a single flux quantum (SFQ) pulse is delivered to each of the one or more qubits. The SFQ pulse is capable of influencing a quantum state of a qubit. The method of delivery of an SFQ pulse may be of various types. In some cases, the method comprises providing a silicon wafer on which an SFQ circuit has been fabricated, and which is flip-chip bonded to the system of qubits. In some cases, the SFQ pulse is delivered to a capacitor pad having a capacitive coupling to a part of the qubit. In these embodiments, the effect of the SFQ pulse on the qubit is described by the time evolution with a qubit Hamiltonian, containing a time-varying classical field which is a function of the voltage of the SFQ pulse, and containing an operator of the qubit. In the cases where the qubit is a transmon qubit, and the SFQ pulse is coupled capacitively, the time evolution of the quantum state of the qubit may be described by the

$$Hamiltonian \hat{H} ( t ) = ℏω {\hat{a}}^{†} \hat{a} + \frac{α}{2} {\hat{a}}^{†} {\hat{a}}^{†} \hat{a} \hat{a} + V ( t ) \cdot {C}_{c} \sqrt{\frac{ℏ ω}{2 C}} \cdot i ( {\hat{a}}^{†} - \hat{a} ) ,$$

where C_{c} is the coupling capacitance, ω is the qubit frequency, α is the qubit anharmonicity, and C is the qubit self-capacitance. In the cases where the duration of an SFQ pulse is much smaller than the qubit period, the time evolution operator in the presence of an SFQ pulse may be described as an instantaneous effect of applying

$$\hat{U} = exp ( \frac{δ θ}{2} ( {\hat{a}}^{†} - \hat{a} ) ) , where δθ = {Φ}_{0} {C}_{c} \sqrt{\frac{2 ω}{ℏ C}}$$

is the SFQ kick angle.

A kick angle may be a measure of the magnitude of the effect that an SFQ pulse has on the state of a physical qubit. In some cases, where the SFQ pulse is delivered to a transmon qubit through capacitive coupling, the effect of the SFQ pulse on the low-energy states of the transmon qubit may be described by a unitary operator

$${\hat{U}}_{δ θ} = exp ( \frac{δ θ}{2} ( {\hat{a}}^{†} - \hat{a} ) ) ,$$

where δθ is the kick angle, â^{†} is the creation operator, and â is the annihilation operator. The frequency of a qubit may be the frequency corresponding to the difference between qubit states of the qubit. For example, a qubit's states may be its lowest and second-lowest eigenenergies of the Hamiltonian describing the dynamics of the qubit. However, in some cases, a qubit's states may be any two states used for quantum computation. The frequency between two states may be described as ω=(E₁−E₀)/h, where ω is the frequency of a qubit, E₀ is the first eigenenergy, E₁ is the second eigenenergy, and h is the reduced Planck constant. Similarly, the period of a qubit may be the period

$$T = \frac{2 π}{ω} .$$

The frequency may be the angular frequency. A frequency ω may be related to the period T as ω=2π/T. An anharmonicity may be the difference between two energy spacings in a sequence of states. For example, an anharmonicity may be described by the difference of the lowest energy spacing and the second-lowest energy spacing. In an example, the lowest energy spacing is the difference between the lowest and second-lowest eigenenergies (E₁−E₀), and the second-lowest energy spacing is the difference between the second-lowest and third-lowest eigenenergies (E₂−E₁). The anharmonicity may be described as α=E₂−2E₁+E₀.

Still referring to FIG. 2 and according to processing operation 206, at least one SFQ pulse schedule is obtained for the one or more qubits. Each schedule comprises on-ramp, resonant and off-ramp parts. In some cases, the on-ramp part is a sequence of arrivals of SFQ pulses, wherein possible arrival times are determined by an SFQ pulse clock, and the sequence's length is determined by a certain number of periods of an SFQ pulse clock frequency. The SFQ pulse clock frequency may be the frequency of a clock which sends trigger signals to the SFQ control circuits at regular intervals. The arrival of a trigger signal at the SFQ control circuit may cause an SFQ pulse to be delivered to a qubit at about the same time. In some cases, no SFQ pulse is delivered to a qubit in the absence of a trigger signal. The SFQ pulse clock frequency may determine the frequency of possible arrival times of SFQ pulses at a qubit. An SFQ pulse clock period may be the period of the clock, which may be the time duration between two subsequent trigger signals.

In some cases, the resonant part is a resonant pulse sequence comprising a pattern of arrivals of SFQ pulses. The pattern may repeat at about a qubit frequency, or at about an integer multiple of a qubit frequency. In some cases, the off-ramp part is a sequence of arrivals of SFQ pulses, wherein possible arrivals are determined by the SFQ pulse clock, and the sequence's length is determined by a certain number of periods of the SFQ pulse clock frequency. In some cases, the off-ramp part is a reversed copy of the on-ramp part. In some cases, the resonant part of the schedule is symmetric in time, that is, the resonant part of the schedule coincides with its own reversed copy. In these embodiments, and if the off-ramp part is also a reversed copy of the on-ramp part, the complete schedule is symmetric in time. For example, suppose the frequency of the SFQ pulse clock is about four times the frequency of a qubit. Further suppose that the on-ramp sequence's length is 8 periods of the SFQ pulse clock, and the on-ramp hence contains 8 possible arrival times. An example on-ramp sequence may be expressed by the string “1000 0100”, where the symbol 1 in the n-th position indicates that an SFQ pulse is scheduled to arrive at the n-th possible arrival time, the symbol 0 indicates that no SFQ pulse is scheduled to arrive, and the space symbol (“ ”) serves as a visual guide for the eye. In the present embodiment, the resonant part of the schedule is formed by repeating the sequence “1000” five times, followed by the sequence “1”. The resonant part of the schedule thus is symmetric in time, and begins with a pulse and ends with a pulse. During the resonant part, an SFQ pulse arrives at the qubit at a regular interval corresponding to about the qubit period, and the duration of the resonant part of the schedule is (4·5+1)=21 SFQ pulse clock periods. The off-ramp sequence may be expressed by the string “001 0000 1”, which is a reversed copy of the string representing the on-ramp. The complete SFQ pulse schedule may therefore be expressed by the string “1000 0100|1000 1000 1000 1000 1000 1|001 0000 1”, where the symbol “|” serves as a visual guide for delineating the three parts of the schedule. The set of SFQ pulse arrival times that form the schedule is then {T_{SFQ}·nₖ}ₖ, where T_{SFQ} is the SFQ pulse clock period, and nₖ are those positions in the string having the symbol “1”, where it is understood that the first character of the string is at position 0. In the present embodiment, nₖ are given by (0, 5, 8, 12, 16, 20, 24, 28, 31, 36).

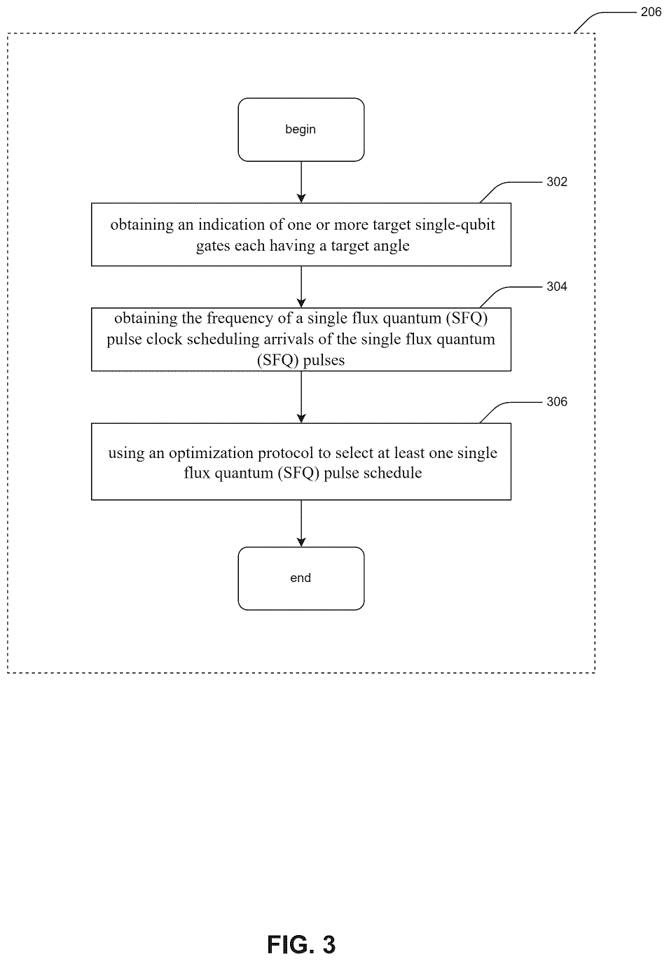

The at least one SFQ pulse schedule may be obtained in various ways. In some cases, the at least one SFQ pulse schedule is obtained following the procedure described herein with respect to FIG. 3.

Now referring to FIG. 3, there is shown a flowchart of an embodiment of a procedure for obtaining at least one SFQ pulse schedule for one or more qubits.

According to processing operation 302, an indication of one or more target single-qubit gates each having a target angle are obtained. The one or more target single-qubit gates may be obtained in various ways. In some cases, the one or more target single-qubit gates are specified by the user. The one or more target single-qubit gates may be of various types. In some cases, the one or more target single-qubit gates comprise a unitary operator

$$\hat{U} = exp ( - \frac{i θ}{2} \hat{Y} ) ,$$

where θ is the target angle and Ŷ is the Pauli-Y matrix, and θ is specified by the user. The target angle may be a single-qubit gate angle. The single-qubit gate angle may be the rotation angle of the rotation of the single-qubit Bloch sphere which corresponds to a given unitary single-qubit gate. In some cases, the one or more target single-qubit gates comprise the Pauli-X, Pauli-Y, or Pauli-Z gates, or the square root or inverse square root of the Pauli-X, Pauli-Y, or Pauli-Z gates, or the Hadamard gate. In some cases, there is one target single-qubit gate having a target angle of

$$θ = \frac{π}{2} .$$

In some cases, an interval of target angles is specified, and there is a target gate corresponding to each target angle in the interval. In some cases, the target gates are expressed in a rotating frame rotating at about a qubit frequency.

Still referring to FIG. 3 and according to processing operation 304, the frequency of an SFQ pulse clock scheduling arrivals of the SFQ pulses is obtained. The frequency of an SFQ pulse clock scheduling arrivals of the SFQ pulses may be obtained in various ways. In some cases, the frequency of an SFQ pulse clock scheduling arrivals of the SFQ pulses is set by adjusting the settings of a tunable clock generator.

Still referring to FIG. 3 and according to processing operation 306, an optimization protocol is used to select at least one SFQ pulse schedule. In some cases, an optimization protocol may be a procedure which is directed to finding those values of one or more variables x which minimize or maximize the value of a real-valued function ƒ(x). The possible values of x may be restricted to be members of a given set or satisfy given constraints. The values of the function ƒ(x) may be known or obtainable approximately or indirectly or as a mean over samples.

In some cases, the optimization protocol may use the one or more target single-qubit gates and the frequency of an SFQ pulse clock scheduling arrivals of the SFQ pulses. Schedules for which all or substantially all of the arrival times of SFQ pulses coincide with arrival times of the SFQ pulse clock signal may be implemented and delivered to a qubit. The optimization protocol may take this constraint into account and select one or more SFQ pulse schedules which can be implemented.

In some cases, selecting the at least one SFQ pulse schedule may comprise selecting the on-ramp and off-ramp parts and the length of the resonant part of the schedule using a figure of merit of a target single-qubit gate. In some cases, the figure of merit comprises comparing the target single-qubit gate to the effect which the schedule has on a quantum state of a qubit. In some cases, the figure of merit comprises an indication of the leakage of the quantum state of the qubit out of the computational Hilbert space. In some cases, the figure of merit comprises an indication of the robustness of the effect of the schedule to fluctuations in the qubit frequency, the SFQ kick angle, SFQ pulse arrival times, or other properties of the qubits or SFQ pulse effects. In some cases, obtaining the figure of merit comprises simulating the quantum state of a qubit to obtain a description of the quantum channel describing the effect of the schedule on the quantum state of the qubit, and the figure of merit is the average gate fidelity between the quantum channel and the target gate. In some cases, the target gate is described by the unitary operator Û_{T} acting on the two-dimensional computational Hilbert space. The effect of the schedule is described by a unitary operator Û acting on a Hilbert space having l dimensions, where the first two dimensions are spanned by the computational states and the remainder of the dimensions are spanned by leakage states. In this embodiment, the average gate fidelity is computed as

$$\overline{F} = \frac{2 + {\vert tr ( {\hat{U}}_{P}^{†} {\hat{U}}_{T} ) \vert}^{2}}{6} ,$$

where Û_{P}=\hat{P}Û\hat{P}^{†}, and \hat{P} is the projector from the l-dimensional Hilbert space onto the computational Hilbert space.

In some cases, since the target single-qubit gate is expressed in a rotating frame, the effect of the SFQ pulse schedule may also be expressed in the rotating frame. When expressed in the rotating frame, the effect of the SFQ pulse schedule depends on the start time of that schedule relative to the reference time and frequency of the rotating frame. In some cases, when the SFQ pulse schedule is provided to the figure of merit, the start time of the schedule may be chosen appropriately in relation to the rotating frame.

In some cases, a plurality of SFQ pulse schedules is obtained, and a plurality of target single-qubit gates is provided, and the figure of merit comprises the average of the figures of merit of one SFQ pulse schedule and one target single-qubit gate. In some cases, the figure of merit comprises the average of the figures of merit of a plurality of qubits. In some cases, a plurality of target gates is provided, and a single SFQ pulse schedule with the associated target gate are obtained, and the figure of merit is the best among the figures of merit between an SFQ pulse schedule and each of the target gates.

In some cases, the on-ramp and off-ramp parts are identical for a plurality of SFQ pulse schedules. In some cases, the on-ramp and off-ramp parts are chosen according to the value of θ mod δθ, where θ is the target angle of a target single-qubit gate, δθ is the SFQ kick angle, and “mod” refers to taking the division remainder. In some cases, the on-ramp and off-ramp parts are identical for a plurality of qubits.

The optimization protocol may be of various types. In some cases, the optimization protocol comprises at least one member of the group consisting of: exhaustive search, gradient-based optimization, gradient-free optimization, genetic algorithms, reinforcement learning, machine learning, heuristics for limiting the search space, tree search, and manual search. In some cases, the target gate is of the form

$$\hat{U} = exp ( - \frac{i θ}{2} \hat{Y} ) ,$$

with a target angle θ, the qubit being a transmon qubit, and SFQ pulses delivered through capacitive coupling. The off-ramp part of the schedule may be fixed to be a reversed copy of the on-ramp part. The duration of the on-ramp may be fixed to be a certain number k of periods of the SFQ pulse clock, such that the duration of the on-ramp contains k possible SFQ pulse arrival times. A list of all possible on-ramp schedules r of length k may be generated. For example, there may be 2^{k} many. For each of the possible on-ramp schedules r, a complex number may be computed as

$${v}_{r} = {\sum }_{j} {e}^{i ω {t}_{j}} ,$$

where tⱼ are the arrival times contained in the on-ramp schedule r and ω is the qubit frequency. In some cases, some schedules are deleted from the list of possible schedules using a heuristic criterion. For example, a schedule r may be deleted if lm(νᵣ)≤0. For each possible on-ramp schedule r, the integer

$${n}_{r} = [ \frac{θ}{δ θ} - 2 Re ( {v}_{r} ) ]$$

is computed, where square brackets indicate rounding to the nearest integer. For each possible on-ramp schedule r, a complete SFQ pulse schedule sᵣ is constructed, containing as a first part the on-ramp schedule r, as a second part a resonant pulse sequence having a duration of (k·nᵣ+1) SFQ pulse clock cycles and containing nᵣ SFQ pulses equally spaced by about a qubit period, and as a third part a reversed copy of the on-ramp schedule r. The optimal schedule may then be identified using exhaustive search, e.g., by obtaining a figure of merit for each SFQ pulse schedule sᵣ, and selecting the schedule having the best figure of merit within the search criteria. In some cases, the resonant part of the SFQ pulse schedule is specified by the user. The number of SFQ pulses contained in the on-ramp, and the number of SFQ pulses contained in the off-ramp, may be specified by the user. A simulation procedure using a classical computer may be provided, which takes as an input the list of SFQ pulse arrival times of the on-ramp schedule and the off-ramp schedule, and returns a figure of merit and a numerical estimation of the gradients of the figure of merit with respect to the arrival times. The figure of merit may be such that it is minimized if the quantum gate implemented by the SFQ pulse schedule coincides with the target gate. An implementation of a penalty term using a classical computer may also be provided. A penalty term may take as an input a list of SFQ pulse arrival times of the on-ramp schedule and the off-ramp schedule and a coefficient and returns the numerical value of a penalty term and a numerical estimation of the gradients of the penalty term with respect to the SFQ pulse arrival times. The penalty term may be such that its numerical value is proportional to the coefficient, and its numerical value is minimized when the SFQ pulse arrival times coincide with arrival times of the SFQ pulse clock signal. The sum of the figure of merit and the penalty term may be minimized using gradient-based optimization. Over the course of the optimization procedure, the coefficient of the penalty term may be gradually increased. At the end of the optimization procedure, each time in the list of arrival times of the on-ramp and off-ramp schedules may be rounded to the nearest arrival time of the SFQ pulse clock signal, and the complete SFQ pulse schedule containing the rounded times is returned to the user.

In some cases, the procedure for obtaining at least one SFQ pulse schedule for one or more qubits may further comprise obtaining properties of the system of qubits allowing for simulation of a quantum state of the system of qubits using a digital computer. The digital computer may be of various types, such as any digital computer disclosed elsewhere herein. In some cases, the digital computer may be the digital computer 8 disclosed herein with respect to FIG. 1.

The properties of the system of qubits may be of various types. In some cases, the properties of the system of qubits comprise properties of individual qubits and properties of interactions between qubits. In some cases, the properties of the system of qubits comprise frequency and anharmonicity of qubits. In some cases, the properties of the system comprise a Hamiltonian describing the evolution of the quantum state of the system in the subspace of interest. In some cases, the properties of the system comprise decoherence rates and Lindblad dissipation operators. In some cases, the properties of the system comprise other descriptions of noise acting on the system, such as noise power spectral densities and noise operators.

In some cases, the procedure for obtaining at least one SFQ pulse schedule for one or more qubits may further comprise obtaining an indication of an SFQ pulse effect on the system of qubits. In some cases, the optimization protocol comprises simulating a quantum state of the system of qubits using a digital computer. The digital computer may be of various types, such as any digital computer disclosed elsewhere herein. In some cases, the digital computer is the digital computer 8 disclosed herein with respect to FIG. 1.

The indication of an SFQ pulse effect on the system of qubits may be of various types. In some cases, the indication of the SFQ pulse effect may be a unitary operator or a quantum channel, approximately describing the effect as an instantaneous event. In some cases, the indication may be a time-dependent operator or time-dependent Lindbladian. In some cases, the indication may include statistical elements, such as statistical fluctuations in the arrival time of the SFQ pulses (so-called “pulse jitter”). The effect on the system of qubits may be of various types. In some cases, the effect on the system of qubits comprises the kick angle, wherein the kick angle comprises a rotation angle of the quantum state of a qubit in Hilbert space resulting from an SFQ pulse. In embodiments where the SFQ pulse is delivered to a transmon qubit through capacitive coupling, the effect of the SFQ

$${\hat{U}}_{δ θ} = exp ( \frac{δ θ}{2} ( {\hat{a}}^{†} - \hat{a} ) ) ,$$

where δθ is the kick angle, â^{†} is the creation operator, and â is the annihilation operator.

Simulation of a quantum system may be of various types. In some cases, simulating a quantum state of the system of qubits comprises encoding a classical description of one or more initial quantum states of the system in a memory of a classical computer, and using numerical methods using the classical computer to obtain a prediction of one or more subsequent states of the system using the provided properties of the system and the provided indication of the SFQ pulse effects on the system. In some cases, simulation of a quantum system comprises simulating the time evolution of a state vector, or obtaining the unitary propagator, or simulating the time evolution of a density matrix, or obtaining a classical description of a quantum channel. In some cases, simulation of a quantum system comprises the quantum trajectory method. In the case where the system of qubits contains a single qubit, having an initial state |ψ(t₀)> at time t₀, and the properties of the system are provided as a Hamiltonian Ĥ, and the indication of the SFQ pulse effects on the system is a unitary operator Û, the simulation during a schedule may be performed as follows. A schedule is provided, beginning at time t₀, and containing a number k of SFQ pulse arrival times {tᵢ}_{1≤i≤k} given in ascending order, and ending at a time tₖ₊₁. The quantum state of the system at time tₖ₊₁ may be obtained by numerically evaluating the expression

$$\vert ψ ( {t}_{k + 1} ) 〉 = exp ( - \frac{i}{ℏ} ℏ ( {t}_{k + 1} - {t}_{k} ) \hat{H} ) {\prod }_{i = k}^{1} ( \hat{U} exp ( - \frac{i}{ℏ} ( {t}_{i} - {t}_{i - 1} ) \hat{H} ) ) \vert ψ ( {t}_{0} ) 〉 .$$

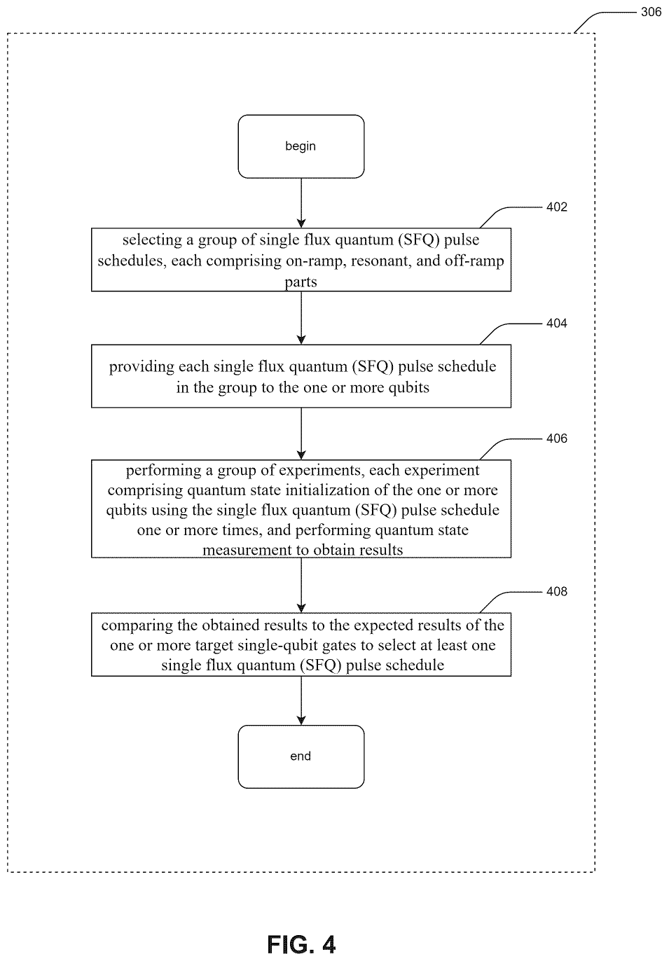

Now referring to FIG. 4 there is shown a flowchart of an embodiment of a procedure for using an optimization protocol to select at least one SFQ pulse schedule.

According to processing operation 402, a group of SFQ pulse schedules, each comprising on-ramp, resonant, and off-ramp parts, is selected.

According to processing operation 404, each SFQ pulse schedule in the group is provided to the one or more qubits. The SFQ pulse schedule may be provided in various ways. In some cases, the SFQ pulse schedule is provided by converting the waveform generated by room-temperature electronics to an SFQ signal with the help of DC-to-SFQ pulse converters. In other embodiments, the encoded schedule is first stored in SFQ-based memory elements as a sequence of bits. Upon request, dedicated SFQ circuitry decodes those bits and converts them into a sequence of pulses to be delivered to the qubit in accordance with an SFQ pulse clock signal arriving from a global clock source which is external to the SFQ circuit.

Still referring to FIG. 4 and according to processing operation 406, a group of experiments is performed. Each single flux quantum (SFQ) pulse schedule may be used one or more times. Each experiment may comprise quantum state initialization of one or more qubits. A sequence of quantum operations may be performed on the one or more qubits. Some of the operations may correspond to one or more SFQ pulse schedules that are delivered to the system of one or more qubits. Quantum state measurement may be performed to obtain results. A measurement may comprise a projective measurement of the state of a qubit, where the result of the measurement is made available to a classical computer. In some cases, multiple experiments may be repeated to collect statistics over the measurements which are used to evaluate a figure of merit. In some cases, the figure of merit may comprise the average gate fidelity or metrics related to the quantification of leakage or unitary over- or under-rotations with respect to a quantum operation. The schedule minimizing the figure of merit, or their weighted sum is selected. In some cases, the group of experiments is performed using the quantum computer 10 disclosed herein with respect to FIG. 1.

Still referring to FIG. 4 and according to processing operation 408, the obtained results are compared to the expected results of the one or more target single-qubit gates to select at least one SFQ pulse schedule.

The one or more target single-qubit gates may be of various types. In some cases, the one or more target single-qubit gates comprise a unitary operator

$$\hat{U} = exp ( - \frac{i θ}{2} \hat{Y} ) ,$$

where θ is the target angle and Ŷ is the Pauli-Y matrix, and θ is specified by the user. In some cases, the one or more target single-qubit gates comprise the Pauli-X, Pauli-Y, or Pauli-Z gates, or the square root or inverse square root of the Pauli-X, Pauli-Y, or Pauli-Z gates, or the Hadamard gate. In some cases, there is one target single-qubit gate having a target angle of

$$θ = \frac{π}{2} .$$

In some cases, an interval or target angles is specified, and there is a target gate corresponding to each target angle in the interval. In some cases, the target gates are expressed in a rotating frame rotating at about a qubit frequency.

In some cases, a list of possible SFQ pulse schedules is constructed (using, e.g., a figure of merit as described elsewhere herein). In some cases, for each schedule, a simulation may be performed as described elsewhere herein, taking as an initial state each computational basis state, to obtain the unitary or superoperator Û describing the effect of the schedule. The figure of merit may be the average gate fidelity between Û and Û_{T} describing the target gate or channel.

Now referring back to FIG. 2 and according to processing operation 208, the at least one SFQ pulse schedule is implemented for the one or more qubits. The implementation comprises delivering an SFQ pulse to a qubit and it may be performed in various ways. In some cases, the implementation method comprises providing a silicon wafer on which an SFQ circuit has been fabricated, and which is flip-chip bonded to the system of one or more qubits. In some cases, the SFQ pulse is delivered to a capacitor pad having a capacitive coupling to a part of a qubit. In some cases, the complete SFQ pulse schedule may be described by the string “1000 0100|1000 1000 1000 1000 1000 1|001 0000 1”. In this example, an SFQ shift register is loaded with the bits “1000 0100”. The SFQ circuit responsible for the resonant pulse sequence is configured for six repetitions and a period of four. A trigger signal may be sent to the SFQ controller, which causes the sequence “1000 0100” to be delivered to a qubit, followed by the resonant pulse sequence “1000 1000 1000 1000 1000 1” having six repetitions and a period of four, followed by the reversed pattern “001 0000 1”.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1. A method for controlling a system of superconducting qubits using at least one single flux quantum (SFQ) pulse schedule, wherein a frequency of an SFQ pulse clock is at about a multiple of a qubit frequency, said method comprising:
(a) delivering an SFQ pulse to one or more qubits of said system of superconducting qubits, wherein said SFQ pulse is configured to influence a quantum state of a qubit;
(b) obtaining said at least one SFQ pulse schedule for said one or more qubits, wherein said at least one SFQ pulse schedule comprises an on-ramp part, a resonant part, and an off-ramp part; and
(c) implementing said at least one SFQ pulse schedule for said one or more qubits.

2. The method of claim 1, wherein said superconducting qubits of said system of superconducting qubits comprise one or more transmon qubits or one or more fluxonium qubits.

3. The method of claim 1, wherein (b) comprises:
(i) obtaining an indication of one or more target single-qubit gates each having a target angle; and
(ii) using an optimization protocol to select said at least one SFQ pulse schedule, wherein said optimization protocol uses said one or more target single-qubit gates and said frequency of said SFQ pulse clock.

4. The method of claim 3, wherein (b) further comprises:
(iii) obtaining properties of said system of superconducting qubits allowing for simulation of a quantum state of said system of superconducting qubits using a digital computer;
(iv) obtaining an indication of an SFQ pulse effect on said system of superconducting qubits;
(v) obtaining said frequency of said SFQ pulse clock; and
(vi) scheduling arrivals of SFQ pulses; wherein said optimization protocol comprises simulating a quantum state of said one or more qubits using said digital computer.

5. The method of claim 3, wherein (ii) comprises:
(1) selecting a group of SFQ pulse schedules, wherein each SFQ pulse schedule in said group comprises on-ramp, resonant, and off-ramp parts;
(2) providing said each SFQ pulse schedule in said group to said one or more qubits;
(3) performing a group of experiments, wherein each experiment comprises: initializing a quantum state of said one or more qubits using said each SFQ pulse schedule one or more times, and performing a quantum state measurement to obtain results; and
(4) comparing said results obtained in (3) to expected results of said one or more target single-qubit gates to select said at least one SFQ pulse schedule.

6. The method of claim 3, wherein said optimization protocol comprises at least one member of the group consisting of exhaustive search, gradient based optimization, gradient-free optimization, genetic algorithms, reinforcement learning, machine learning, heuristics for limiting the search space, tree search, and manual search.

7. The method of claim 4, wherein said properties of said system of said one or more qubits comprise properties of individual qubits and properties of interactions between said one or more qubits.

8. The method of claim 4, wherein said indication of said SFQ pulse effect on said system of said one or more qubits comprises a kick angle, wherein said kick angle comprises a rotation angle of a quantum state of a qubit in a Hilbert space resulting from an SFQ pulse.

9. The method of claim 4, wherein said properties of said system of said one or more qubits comprise a frequency and an anharmonicity of each of said one or more qubits.

10. The method of claim 1, wherein said on-ramp part comprises a sequence of arrival times of said SFQ pulses, wherein arrival times within said sequence of arrival times of said SFQ pulses are determined at least in part by said SFQ pulse clock, and wherein a length of said sequence is determined at least in part by a number of periods of said SFQ pulse clock frequency.

11. The method of claim 1, wherein said resonant part comprises a resonant pulse train comprising a pattern of arrivals of SFQ pulses, wherein said pattern of arrivals repeats at about a qubit frequency.

12. The method of claim 1, wherein said off-ramp part comprises a sequence of arrivals of said SFQ pulses, wherein arrival times within said sequence of arrival times are determined at least in part by said SFQ pulse clock, and wherein a length of said sequence of arrival times is determined at least in part by a number of periods of said SFQ pulse clock frequency.

13. The method of claim 1, wherein said off-ramp part is a reversed copy of said on-ramp part.

14. The method of claim 3, wherein (ii) comprises selecting said on-ramp part, said off-ramp part, and a length of said resonant part of said at least one SFQ pulse schedule based at least in part on a figure of merit of said one or more target single-qubit gates.

15. The method of claim 14, wherein said figure of merit comprises an average of figures of merit of a plurality of said target single-qubit gates.

16. The method of claim 14, wherein said figure of merit comprises an average of figures of merit of a plurality of qubits.

17. The method of claim 3, wherein said on-ramp part and said off-ramp part are substantially identical for a plurality of said target single-qubit gates.

18. The method of claim 1, wherein said on-ramp part and said off-ramp part are substantially identical for a plurality of qubits of said one or more qubits.

19. A system for scheduling single flux quantum (SFQ) pulses of a qubit, said system comprising: a quantum computer controlled by SFQ control electronics having (i) a quantum chip comprising one or more qubits, and (ii) a control/readout system, wherein said quantum computer is communicatively coupled to a digital computer, said digital computer comprising a processor and a memory with instructions stored thereon which when executed by the processor are configured to at least: (1) obtain at least one SFQ pulse schedule for said one or more qubits, wherein said at least one schedule comprises an on-ramp part, a resonant part, and an off-ramp part; and (2) instruct said quantum computer to implement said at least one SFQ pulse schedule for said one or more qubits.

20. The system of claim 19, further comprising a cryogenic device comprising different cryogenic stages at different cryogenic temperatures; wherein said quantum computer is coupled to said cryogenic device and cooled by said cryogenic device at a first cryogenic stage of said cryogenic device at a first cryogenic temperature; and further wherein said SFQ control electronics are coupled to said cryogenic device and cooled by said cryogenic device at a second cryogenic stage of said cryogenic device at a second cryogenic temperature.
